(19) United States
(12) Patent Application Publication
(10) Pub. No.: US 2026/0018459 A1
(43) Pub. Date: Jan. 15, 2026

(54) SEMICONDUCTOR STRUCTURE INCLUDING ISOLATION ELEMENTS WITH ETCHING-RESISTANT UPPER PORTIONS AND METHOD FOR MANUFACTURING THE SAME

(71) Applicant: TAIWAN SEMICONDUCTOR MANUFACTURING COMPANY, LTD., Hsinchu (TW)

(72) Inventors: Wei-Chih Wang, Hsinchu (TW); Wei-Hao Liao, Hsinchu (TW); Hsi-Wen Tien, Hsinchu (TW); Chih Wei Lu, Hsinchu (TW); Yu-Teng Dai, Hsinchu (TW)

(73) Assignee: TAIWAN SEMICONDUCTOR MANUFACTURING COMPANY, LTD., Hsinchu (TW)

(21) Appl. No.: 18/769,984

(22) Filed: Jul. 11, 2024

(51) Int. Cl. H01L 21/768; C08G 63/00; C08G 73/06; C08G 75/24; C08G 77/46; H01L 23/522

(52) U.S. Cl. CPC H01L 21/76831; C08G 63/00; C08G 73/0672; C08G 75/24; C08G 77/46; H01L 21/76802; H01L 21/76819; H01L 21/76837; H01L 21/76877; H01L 23/5226

(57) ABSTRACT

A method for manufacturing a semiconductor structure includes: forming first conducting portions that are spaced apart from each other on a base structure; forming isolation elements, each of which includes a dielectric lower portion and an etching-resistant upper portion covering the dielectric lower portion, the etching-resistant upper portion being made of an etching-resistant material different from a dielectric material of the dielectric lower portion, each of the isolation elements being isolated and exposed from two adjacent ones of the first conducting portions; sequentially forming an etch stop layer and an interlayer dielectric over the first conducting portions and the isolation elements; forming a cavity which extends through the etch stop layer and the interlayer dielectric, and which exposes one of the first conducting portions; and filling the cavity with a second conducting portion.

### BACKGROUND

In advanced back-end-of-line (BEOL) interconnect, when adjacent metal lines are positioned close to each other, time-dependent dielectric breakdown (TDBB) is liable to deterioration. In addition, it is important to maintain a low capacitance between adjacent metal lines so that RC delay of the BEOL interconnect is kept small.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 12 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including isolation elements, and a method for manufacturing the same. The isolation elements are configured to separate conducting elements, such as metal lines or metal vias of interconnecting levels at back-end-of-line (BEOL) of the semiconductor structure, but are not limited thereto. The isolation elements each includes a lower portion that is made of a dielectric material, and an upper portion that covers the lower portion and that is made of an etching-resistant material which is different from the dielectric material. The etching-resistant material exhibits a comparatively higher resistivity to an etching process than the dielectric material, such that the upper portion is capable of resisting the etching process, and is prevented from being etched or damaged during the etching process to undesirably form a void in the isolation elements. As an upper interconnect level is formed on a lower interconnect level, the intactness of the isolation elements at the lower interconnect level may effectively avoid tiger tooth defect in the semiconductor structure (in other words, in this case, a conducting element at the upper interconnect level does not extend into a damage portion of the isolation element at the lower interconnect level to have a tiger tooth shaped cross-section), thus avoid a deterioration of time-dependent dielectric breakdown (TDBB) and at the same time keeping capacitance between conducting elements at the upper and lower interconnect levels low to reduce RC-delay of the semiconductor structure.

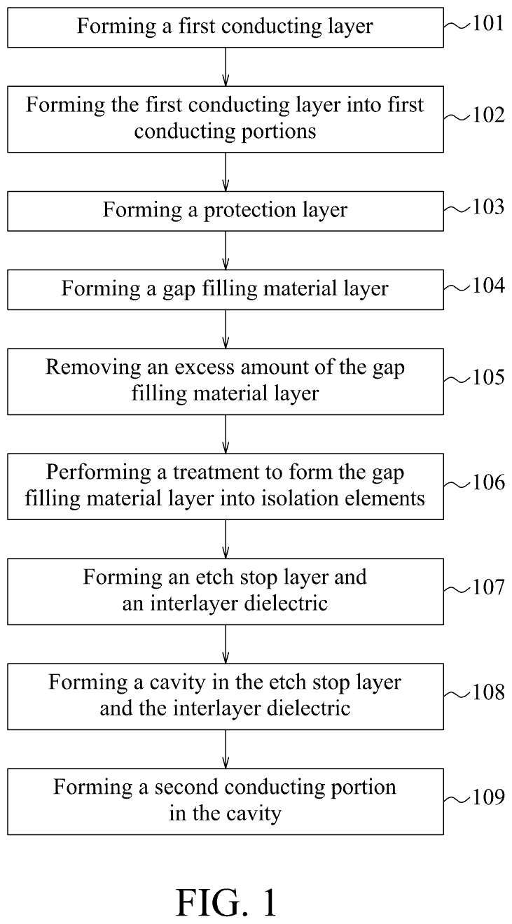

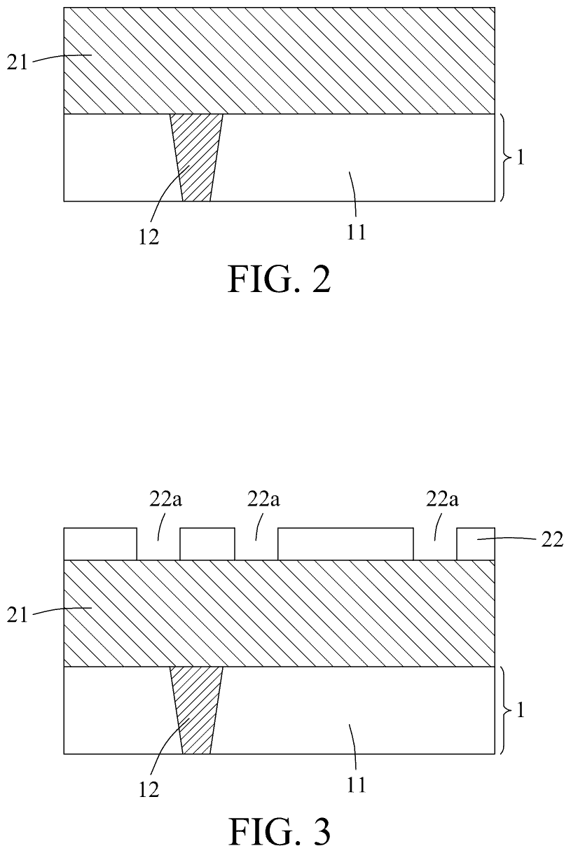

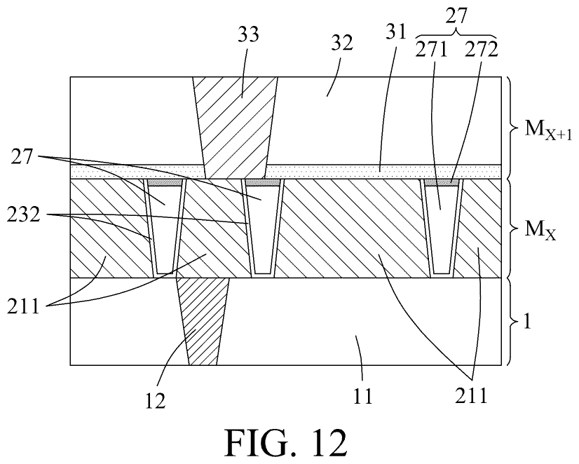

FIG. 1 is a flow diagram illustrating a method for manufacturing the semiconductor structure (for example, the semiconductor structure shown in FIG. 12) in accordance with some embodiments. FIGS. 2 to 12 illustrate schematic views of intermediate stages of the method in accordance with some embodiments. Some repeating structures are omitted in FIGS. 2 to 12 for the sake of brevity. Additional steps can be provided before, after or during the method, and some of the steps described herein may be replaced by other steps or be eliminated.

Referring to FIG. 1 and the example illustrated in FIG. 2, the method begins at step 101, where a first conducting layer 21 is formed on a base structure 1.

The base structure 1 may include a front-end-of-line (FEOL) portion (not shown), a middle-end-of-line (MEOL) portion (not shown), a back-end-of-line (BEOL) portion, and/or any other suitable elements. The FEOL portion may be a logic circuitry with transistors, a memory circuitry having memory elements, or the likes, or combinations thereof, but are not limited thereto, but is not limited thereto. The MEOL portion may include contacts that are electrically connected to the FEOL portion, or the likes, but are not limited thereto. The BEOL portion may include metal lines or vias, or the likes, or combinations thereof, but are not limited thereto. As shown in FIG. 2, the BEOL portion exemplarily includes a via 12 formed in and exposed from an interlayer dielectric (ILD) 11. The ILD 11 may include a low k material, carbon-doped hydrogenated silicon oxide (SiOₓC_{y}H_{z}), silicon oxide (SiOₓ), silicon carbon nitride (SiCN), oxygen-doped carbide (ODC), nitrogen-doped carbide (NDC), tetraethyl orthosilicate (TEOS), silicon nitride (SiNx), other suitable materials, or combinations thereof, but are not limited thereto. The via 12 may include copper (Cu), ruthenium (Ru), tungsten (W), titanium (Ti), aluminum (Al), cobalt (Co), molybdenum (Mo), iridium (Ir), rhodium (Rh), other suitable materials, or combinations thereof, but are not limited thereto. Other suitable materials for the ILD 11 and the via 12 are within the contemplated scope of the present disclosure.

The first conducting layer 21 may include, but are not limited thereto. The first conducting layer 21 may be formed using any suitable deposition method, such as chemical vapor deposition (CVD), atomic layered deposition (ALD), physical vapor deposition (PVD), or the likes, or combinations thereof. Other suitable materials and/or methods for forming the first conducting layer 21 are within the contemplated scope of the present disclosure.

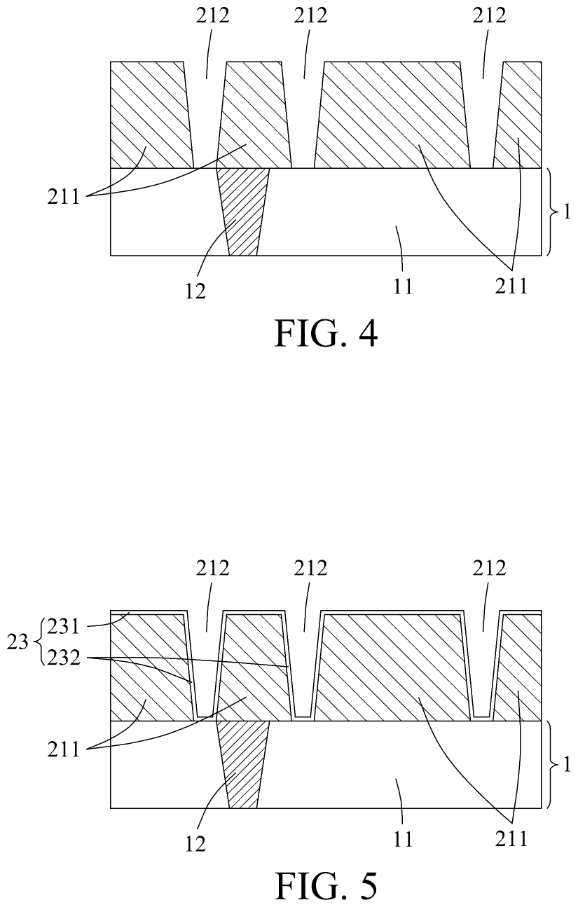

Referring to FIG. 1 and the examples illustrated in FIGS. 3 and 4, the method proceeds to step 102, where the first conducting layer 21 is patterned and formed into first conducting portions 211 that are spaced apart from each other by trenches 212.

Specifically, as shown in FIG. 3, a patterned hard mask 22 is formed on the first conducting layer 21. The patterned hard mask 22 has openings 22a that define location and shape of the trenches 212.

As shown in FIG. 4, the first conducting layer 21 is patterned through the hard mask 22 to form the trenches 212 and the first conducting portions 211. The first conducting portions 211 are spaced apart from each other. Each of the trenches 212 serves as a spaced-apart region to isolate two adjacent ones of the first conducting portions 211. Each of the trenches 212 is bordered by a sidewall of each of the two adjacent first conducting portions 211, and a portion of upper surface of the base structure 1. That is, the upper surface of the base structure 1 is exposed from the trenches 212. In the cross section shown in FIG. 4, the via 12 of the base structure 1 is in direct contact, and thus, electrically connected to, one of the first conducting portions 211. The patterning process may be any suitable etching process known in the art. In some embodiments, metal reactive ion etching (RIE) is adopted, but is not limited thereto. In some embodiments, each of the first conducting portions 211 may have a width ranging from 5 nm to about 5000 nm.

Referring to FIG. 1 and the examples illustrated in FIG. 5, the method proceeds to step 103, where a protection layer 23 is formed over the first conducting portions 211 and in the trenches 212.

The protection layer 23 is formed to protect the first conduction portions 211, i.e., preventing the first conduction portions 211 from direct contact with any plasma used in subsequent processes that may undesirably cause damage, or oxidation of the materials of the first conduction portions 211. The protection layer 23 is conformally formed over the structure shown in FIG. 4. Specifically, the protection layer 23 has portions 231 that are respectively formed on upper surfaces of the first conduction portions 211 opposite to the base structure 1, and portions 232 that are respectively formed along the trenches 212, e.g., sidewalls of the first conducting portions 211, and portions of the upper surface of the base structure 1 that are exposed from the trenches 212.

In some embodiments, the protection layer 23 include silicon carbide (SiC), silicon oxycarbide (SiOC), silicon oxynitride (SiON), silicon oxide (SiO₂), silicon nitride (SiN), silicon carbonitride (SiCN), other suitable materials, or combinations thereof, but are not limited thereto. The protection layer 23 may be formed using any suitable deposition process known in the art, such as CVD, ALD, PVD, but are not limited thereto. In other embodiments, the protection layer 23 has a thickness ranging from about 10 Å to about 100 Å, but is not limited thereto. Other suitable materials, methods and/or dimensions for forming the protection layer 23 are within the contemplated scope of the present disclosure.

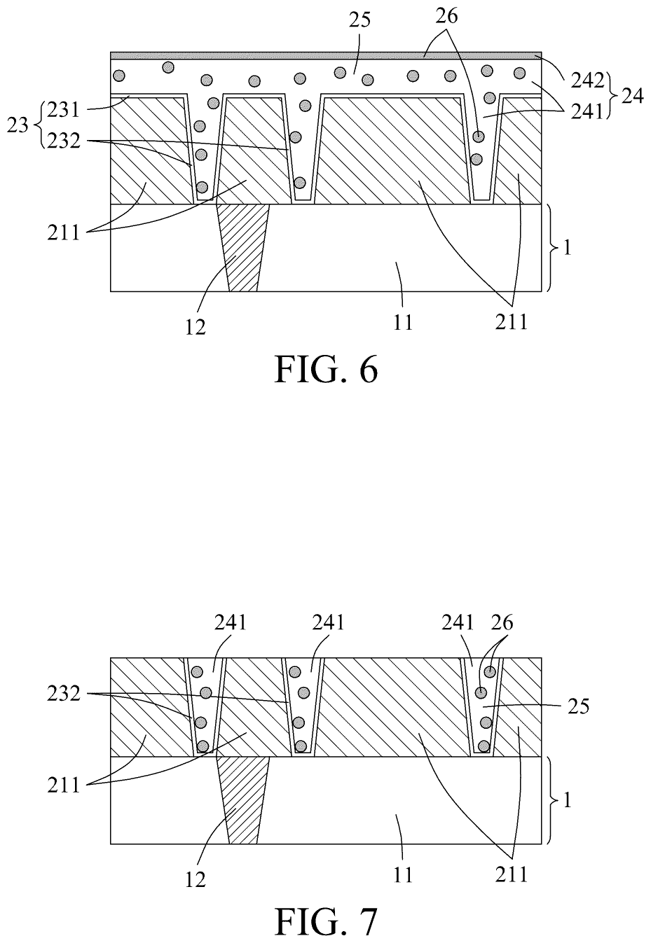

Referring to FIG. 1 and the example illustrated in FIG. 6, the method proceeds to step 104, where a gap filling material layer 24 is formed over the protection layer 23 and filling the trenches 212.

The gap filling material layer 24 is formed by depositing a mixture that includes a dielectric material 25 and an etching-resistant material 26. In some embodiments, before the deposition process, the mixture is first prepared by mixing the dielectric material 25 and the etching-resistant material 26 together. The mixing process may be performed at room temperature or other suitable temperature.

The dielectric material 25 may be similar to the material of the ILD 11, and details thereof are omitted for the sake of brevity. In some embodiments, the dielectric material 25 has a low dielectric constant value, and is known as a low-K dielectric material.

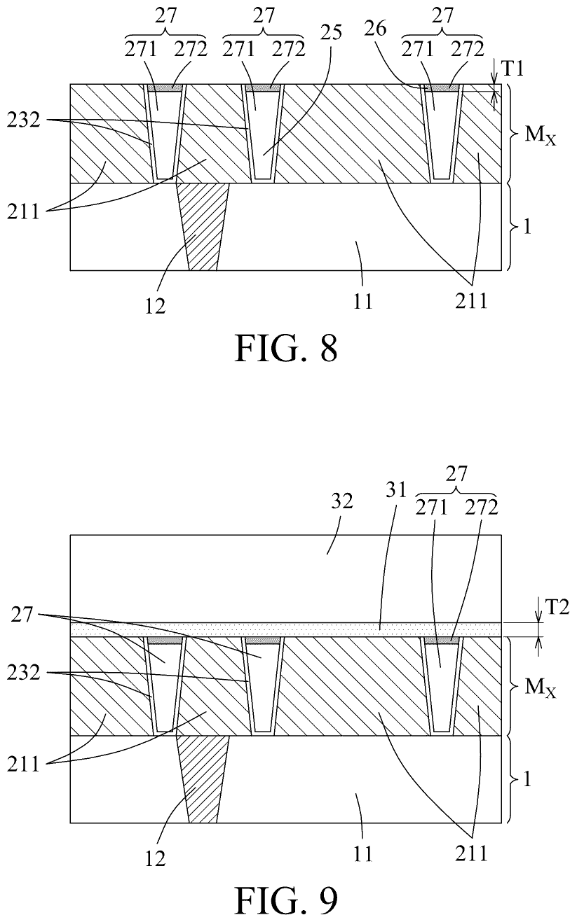

In certain embodiments, the etching-resistant material 26 accounts for about 1 wt % to about 10 wt % based on 100 wt % of the mixture. Such range is appropriate to permit a sufficient amount of the etching-resistant material 26 to form an etching-resistant upper portion 272 (see FIG. 8, will be further described later), and it is noted that the subsequent process will not benefit from an excess amount of the etching-resistant material 26. For example, when the amount of the etching-resistant material 26 is less than about 1 wt %, the etching-resistant upper portion 272 formed may not have a sufficient thickness for protecting a dielectric lower portion 271 (see FIG. 8) therebeneath. When the amount of the etching-resistant material 26 is greater than about 10 wt %, after segregation of the mixture to form the dielectric lower portion 271 and the etching-resistant upper portion 272 (see FIG. 8), there could be a small amount of the etching-resistant material 26 undesirably remaining in the dielectric lower portion 271, which might not benefit reduction of capacitance.

The etching-resistant material 26 has a surface energy lower than that of the dielectric material 25, and is known as a surface segregate material. Upon mixing of the etching-resistant material 26 and the dielectric material 25, a part of the etching-resistant material 26 is soluble and randomly dispersed in the dielectric material 25 (such part is referred as the soluble part hereinafter), while another part of the etching-resistant material 26 segregates from the dielectric material 25 and floats in the dielectric material 25 (such part is referred as the floating part hereinafter). The term “soluble” in this disclosure means two materials are well mixed and are not segregated from each other.

In some embodiments, the etching-resistant material 26 is a polymer having a molecular weight ranging from about 1000 to about 300000. If the molecular weight is too high, the etching-resistant material 26 might not have sufficiently low surface energy, to float in the dielectric material 25. If the molecular weight is too low, the etching-resistant material 26 might not have sufficient etching resistivity. In some embodiments, the etching-resistant material 26 has a dielectric constant (ranging from about 2 to about 4) which is in relation with the molecular weight of the etching-resistant material 26.

The polymer may include a backbone having a repeating unit with various types of side chain. In some embodiments, the polymer has a fluorinated side chain. In certain embodiments, the polymer has a silicon-containing side chain. The fluorinated side chain, or the silicon-containing side chain may facilitate the polymer to acquire sufficiently low surface energy. In other embodiments, the polymer has an alkyl side chain, which may facilitate solubility of the polymer (i.e., the etching-resistant material) in the dielectric material. Other suitable types of side chain of the polymer are within the contemplated scope of the present disclosure. In accordance with some embodiments, the polymer has at least one type, or combinations of different types, of the aforementioned types of side chain. The aforementioned types of side chain may each have a predetermined length (by varying, e.g., number of carbon atom, or number of silicon atom in the side chain) in order to achieve the different effects as discussed.

The repeating unit in the backbone of polymer may include one or more phenyl groups, and thus may be referred to as a phenyl-containing repeating unit. For instance, in some embodiments, the phenyl-containing repeating unit in the backbone of the polymer may have at least two, or more, of phenyl groups. Inclusion of phenyl groups in the backbone permits the polymer to exhibit etching resistivity in certain etching process, and details thereof will be further described in subsequent step.

In some embodiments, the polymer has the following formula (A):

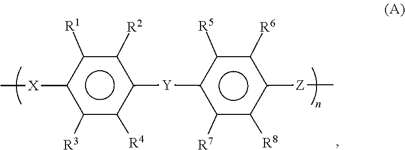

In the formula (A), X represents

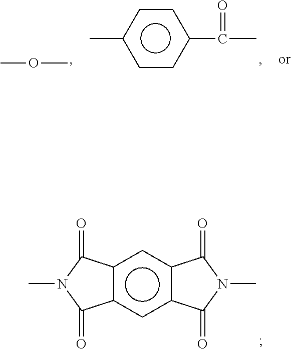

Y represents

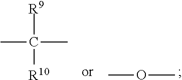

and Z represents

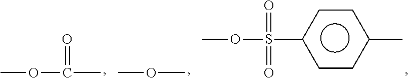

or a single bond. It can be seen that, depending on which one of combinations of X and Z as illustrated above, the polymer may have two or more phenyl groups per repeating unit of the polymer. Each of R¹, R², R³, R⁴, R⁵, R⁶, R⁷, R⁸, R⁹, R¹⁰ independently represents one of the following formula (I), formula (II), or formula (III):

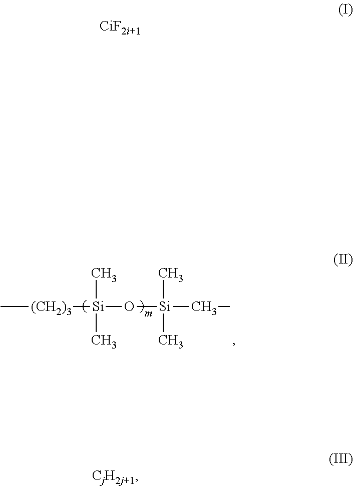

In formula (I), i is an integer equal to or larger than 1, and not greater than 12. Formula (I) serves as the aforementioned fluorinated side chain. Examples of formula (I) include CF₃, C₂F₅, C₃F₇, C₄F₉, C₅F₁₁, C₆F₁₃, C₇F₁₅, C₈F₁₇, CoF₁₉, C₁OF₂₁, CHF₂₃, and C₁₂F₂₅. In formula (II), m is an integer equal to or larger than 0, and not greater than 12. Formula (II) serves as the aforementioned silicon-containing side chain. In formula (III), j is an integer equal to or larger than 0, and not greater than 12. Formula (III) serves as the aforementioned alkyl side chain. Examples of formula (III) include H, CH₃, C₂H₅, C₃H₇, C₄H₉, C₅H₁₁, C₆H₁₃, C₇H₁₅, C₈H₁₇, C₉H₁₉, C₁₀H₂₁, CuH₂₃, and C₁₂H₂₅. It is noted that by having the specified number of carbon atom, fluorine atom or silicon atom (e.g., j in formula (III), and/or m in formula (II), and/or i in formula (I)) in the side chain, the etching-resistant material 26 can achieve sufficient solubility (in the dielectric material 25), and/or has sufficiently low surface energy.

In some embodiments, the polymer has the following formula (A-1):

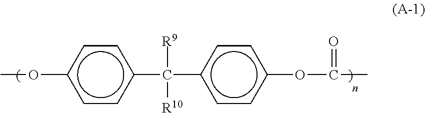

In other embodiments, the polymer has the following formula (A-2):

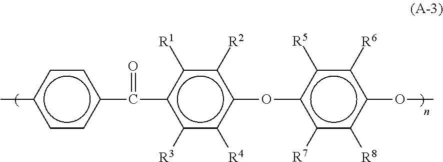

In some other embodiments, the polymer has the following formula (A-3):

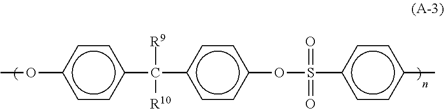

In yet other embodiments, the polymer has the following formula (A-4):

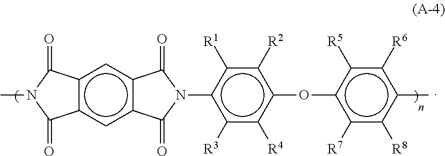

After the mixing process, the mixture obtained is deposited over the structure shown in FIG. 5, so as to form the gap filling material layer 24 as shown in FIG. 6. The deposition process may be performed using any suitable process known in the art. In some embodiments, a spin-on coating process is employed. In other embodiments, CVD, ALD or PVD are used, but are not limited thereto. Other suitable processes for forming the gap filling material layer 24 are within the contemplated scope of the present disclosure.

Referring to FIG. 6, the etching-resistant material 26, including both the floating part and the soluble part, is illustrated with a grey shading, while the dielectric material 25, is illustrated without any shading hereinafter. The gap filling material layer 24 includes a lower section 241 and an upper section 242. The lower section 241 includes the dielectric material 25, and the soluble part of the etching-resistant material 26. As shown in FIG. 6, the soluble part is represented by various circles to illustrate that the polymer of the etching-resistant material 26 is soluble and randomly dispersed in the dielectric material 25. In addition, the lower section 241 is located in the trenches 212 (see FIG. 5), and on the upper surfaces of each of the first conduction portions 211. The upper section 242 includes merely the floating part of the etching-resistant material 26 and covers a top surface of the lower section 241.

Referring to FIG. 1 and the examples illustrated in FIG. 7, the method proceeds to step 105, where an excess amount of the gap filling material layer 24 is removed.

Specifically, referring back to FIG. 6, the upper section 242, and a portion of the lower section 241 of the gap filling material layer 24 are removed. That is, the floating part of the etching-resistant material 26 is removed. In addition, the dielectric material 25 located on the upper surfaces of the first conducting portions 211 along with some of the soluble part of the etching-resistant material 26 distributed therein, are also removed. In some embodiments, portions 231 of the protection layer 23 that are located above the upper surfaces of the first conduction portions 211 are also removed. In certain embodiments, step 105 is performed by conducting a planarization process, such as a chemical-mechanical planarization (CMP), but is not limited thereto, to expose the upper surfaces of the first conduction portions 211. As such, after performing step 105, the remaining lower section 241 at this stage, includes several parts that are respectively located in the trenches 212 (see FIG. 5). Each of the parts has a single layer structure to include the remaining dielectric material 25, and some of the soluble part of the etching-resistant material 26 distributed within the remaining dielectric material 25.

Referring to FIG. 1 and the examples illustrated in FIG. 8, the method proceeds to step 106, where a treatment is performed to permit segregation of the mixture, so as to form isolation elements 27.

Specifically, the soluble part of the etching-resistant material 26 that is originally soluble and distributed in the dielectric material 25 segregates from the dielectric material 25 at this stage and forms a film on top of the dielectric material 25 due to the etching-resistant material 26 having the surface energy lower than that of the dielectric material. For instance, for each of the parts of the remaining lower section 241, the soluble part of the etching-resistant material 26 that is illustrated as the grey circles as shown in FIG. 7 forms a continuous layer that is illustrated as a grey layer on top of the dielectric material 25 as shown in FIG. 8.

As such, the parts of the remaining lower section 241 (see FIG. 7), each of which having a single-layer structure, are respectively formed into isolation elements 27 (sec FIG. 8), each of which having a bi-layered structure. As shown in FIG. 8, each of the isolation elements 27 includes a dielectric lower portion 271 (without shading) which constitutes the dielectric material 25, and an etching-resistant upper portion 272 (with grey shading) which constitutes the etching-resistant material 26. The etching-resistant upper portion 272 covers the dielectric lower portion 271, so that the dielectric lower portion 271 is prevented from being exposed from the adjacent first conducting portions 211. In certain embodiments, the etching-resistant upper portion 272 consists of one layer of polymer molecules, but not multiple layers of polymer molecules that are stacked on one another. In other words, the etching-resistant material 26 is formed as a monolayer, i.e., the etching-resistant upper portion 272 may be a one-polymer-molecule thick layer. In some embodiments, the etching-resistant upper portion 272 may have a thickness (T 1—) ranging from about 2 Å to about 100 Å. Such thickness range mainly depends on the molecular weight of the polymer as described with reference to FIG. 6 (for example, when the side chain of the polymer is relatively long or the molecular weight of the polymer is relatively large, the etching-resistant upper portion 272 has a relatively large thickness). Because of the presence of etching-resistant upper portion 272, the isolation elements 27 of the present disclosure each has an upper surface that exhibits certain etching resistivity (in comparison with the dielectric lower portion 271), which will be further described in subsequent steps. In addition, it is found that the isolation elements 27 of the present disclosure each has an upper surface that exhibits improved hydrophobicity, resulting in improved device stability of the semiconductor structure.

In some embodiments, the treatment is a baking process. The baking process may be conducted at a temperature ranging from about 50° C. to about 450° C. If the temperature is too low (e.g., lower than 50° C.), there may be insufficient energy to make the etching-resistant material 26 segregates from the dielectric material 25. If the temperature is too high (e.g., higher than 450° C.), the heat energy may damage other elements of the structure.

In view of the above, please note that it is important for the etching-resistant material 26 to have sufficiently low surface energy (the surface energy may be adjusted by determining the type of side chain and molecular weight of the polymer) so that the soluble part of the etching-resistant material 26 which is originally soluble in the dielectric material 25 (see FIG. 6) can be segregated from the dielectric material 25 after the baking process as shown in FIG. 8. In addition, it is also critical to achieve a balance between the low surface energy and the solubility of the etching-resistant material 26 in the dielectric material 25 (the property of the etching-resistant material 26 may be adjusted by the type of side chain in the polymer), so that the amount of the etching-resistant material 26 that is soluble and dispersed in the dielectric material 25 (the soluble part) as described in step 104 with reference to FIG. 6 is sufficient. In some cases, an unduly large amount of the etching-resistant material 26 segregating from the dielectric material 25 immediately after deposition of the mixture serves as the floating part and thus form the upper section 242 (see FIG. 6), leaving only a small amount of the etching resistant material 26 which remains soluble in the dielectric material 25 to serve as the soluble part. Please note that the floating part (the upper section 242) of the etching-resistant material 26 will be removed in the subsequent CMP process (see FIG. 7), and that the soluble part of the etching-resistant material 26 remaining in the dielectric material 25 may be insufficient to form the etching-resistant upper portion 272 as shown in FIG. 8.

After step 106, a lower interconnect level Mx is formed to include the first conducting portions 211, and the isolation elements 27. The first conducting portions 211 may each serve as a metal line. The isolation elements 27 each isolates and is exposed from two adjacent ones of the first conducting portions 211.

Referring to FIG. 1 and the example illustrated in FIG. 9, the method proceeds to step 107, where an etch stop layer (ESL) 31 and an ILD 32 are sequentially formed over the lower interconnect level Mx, i.e., the first conducting portions 211 and the isolation elements 27.

Any suitable deposition process known in the art, such as CVD, ALD, PVD, but are not limited thereto, may be used to form the ESL 31 and the ILD 32. In some embodiments, the ESL 31 may include a high k dielectric material, silicon carbon nitride (SiCN), carbon-doped hydrogenated silicon oxide (SiOₓC_{y}H_{z}), silicon oxide (SiOₓ), silicon nitride (SiNₓ), aluminum oxynitride (AlOₓN_{y}), a metal oxide (e.g., aluminum oxide (AlOₓ), carbon-doped aluminum oxide (C:AlO), zirconium oxide (ZrOₓ)), oxygen-doped carbide (ODC), nitrogen-doped carbide (NDC), tetraethyl orthosilicate (TEOS), other suitable materials, or combinations thereof. In some embodiments, the material of the ESL 31 is different from the material of the dielectric material 25. In certain embodiments, the ESL 31 may have a thickness (T2) ranging from about 10 Å to about 70 Å. The ILD 32 may include a material similar to that of the ILD 11, and details thereof are not repeated for the sake of brevity. Other suitable materials for forming the ESL 31 and the ILD 32 are within the contemplated scope of the present disclosure.

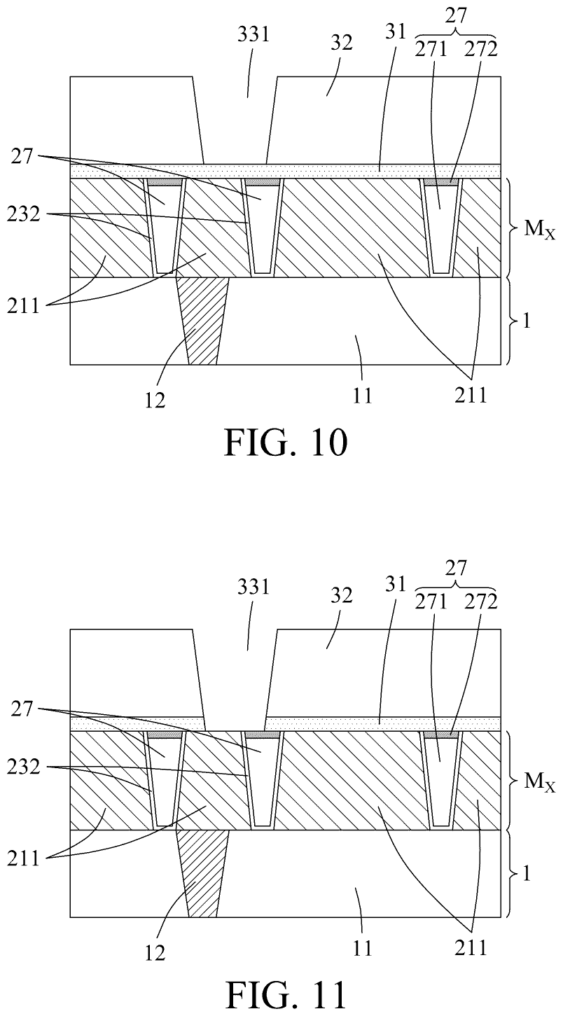

Referring to FIG. 1 and the example illustrated in FIGS. 10 and 11, the method proceeds to step 108, where a cavity 331 is formed.

In some embodiments, step 108 includes two sub-steps, which are respectively shown in FIGS. 10 and 11. For instance, in FIG. 10, a first sub-step may be a patterning process. The patterning process is performed to form the cavity 331 extending through the ILD 32 so as to expose a portion of the ESL 31 underneath. In some embodiments, the patterning process may include: forming a photoresist (not shown) on the ILD 32; exposing the photoresist through a photomask (not shown); developing the photoresist to form a patterned photoresist (not shown); and patterning the ILD 32 through the patterned photoresist using any suitable etching process. Other methods for performing the patterning process are within the contemplated scope of the present disclosure.

In FIG. 11, a second sub-step may include removing the exposed portion of the ESL 31 through the cavity 331, so that a conducting element, e.g., one of the first conducting portions 211, of the lower interconnect level Mx underneath is exposed through the cavity 331 (i.e., the cavity 331 further extends through the ESL 31). Such removal of the exposed ESL 31 may be known as an ESL breakthrough process. Any suitable process known in the art, such as a dry etching process, but is not limited thereto, may be used to remove the exposed portion of the ESL 31. In the exemplary example shown in FIG. 11, a second leftmost one of the first conducting portion 211 is exposed through the cavity 311. After the second sub-step, the patterned photoresist formed in the first sub-step is removed.

Please note that, the patterning process described with reference to FIG. 10, ideally, exposes the portion of the ESL 31 which corresponds in position to the conducting element that is to be exposed after the ESL breakthrough process as shown in FIG. 11. In some cases, due to overlay issue during the patterning process (e.g., the cavity 331 formed using the patterned photoresist that has the overlay issue is not perfectly aligned with and is slightly shifted relative to the second leftmost first conducting portion 211), the exposed portion of the ESL 31 is then, corresponds in position to the corresponding first conducting portion 211, as well as an adjacent one of the isolation elements 27. As such, after the ESL breakthrough process, the adjacent isolation element 27 may also be unintentionally exposed. In the exemplary example shown in FIG. 11, a middle one of the isolation element 27 is partially exposed from the cavity 331 in addition to the second leftmost first conducting portion 211.

In some cases (not shown), in each of the isolation elements, the etching-resistant upper portion is absent, and the dielectric lower portion is in direct contact with the ESL. During the ESL breakthrough process, such isolation elements are liable to damage because the ESL breakthrough process may have a relatively low selectivity between the ESL and the dielectric lower portion. For instance, the ESL breakthrough process may have a selectivity to the ESL with respect to the dielectric lower portion ranging from about 1 to about 2 (in other words, an etching rate of the ESL is about one to two times greater than an etching rate of the dielectric lower portion). That is, in the ESL breakthrough process, the dielectric lower portion underneath the ESL is also liable to the etching process and thus may also be undesirably etched and damaged to form a void in the dielectric lower portion. The void may extend from an upper surface of the dielectric lower portion toward the base structure, and is likely to be filled in any steps performed subsequently.

In contrast, in accordance with the present disclosure, the isolation elements 27 are each formed with the etching-resistant upper portion 272 covering the dielectric lower portion 271. Due to the phenyl-group-rich backbone of the etching-resistant material 26 (see FIG. 6), the etching-resistant upper portion 272 made from such etching-resistant material 26 exhibits a high etching resistivity to the ESL breakthrough process, so that the etching selectivity between the ESL 31 and the etching-resistant upper portion 272 is enhanced. For instance, the ESL breakthrough process may have a selectivity to the ESL 31 with respect to the etching-resistant upper portion 272 ranging from about 5 to about 10 (in other words, an etching rate of the ESL 31 is about five to ten times greater than an etching rate of the etching-resistant upper portion 272). That is, even if the patterned photoresist has the overlay issue, the isolation element(s) 27 underneath the exposed ESL 31 (see FIG. 10) may still remain intact and not affected by the formation of the cavity 331, or more specifically, not affected by the ESL breakthrough process. In other words, the method of the present disclosure avoids the formation of voids in the isolation elements 27. In some embodiments, the isolation element(s) 27 may be further protected by adjusting thickness (T2) of the ESL 31 (see FIG. 9), so as to reduce a time period of the isolation element(s) 27 being exposed to an etchant used in the ESL breakthrough process.

In view of the aforesaid, in order to form the etching-resistant upper portion 272, parameters (e.g., side chain, backbone, molecular weight of the polymer) of the etching-resistant material 26 for forming the etching-resistant upper portion 272 should be carefully determined to achieve a balance between sufficient etching resistivity, floating (in the dielectric material) and solubility (in the dielectric material) of the etching-resistant material 26. In addition, amount of the etching-resistant material 26 in the mixture (for forming the gap filling material layer 24, see FIG. 6) is also critical to ensure that the amount of the etching-resistant material 26 that is soluble in the dielectric material 25 in the trenches 212 (see FIG. 5) is sufficient to subsequently form the etching-resistant upper portion 272.

Referring to FIG. 1 and the example illustrated in FIG. 12, the method proceeds to step 109, where a second conducting portion 33 is formed in the cavity 331 (see FIG. 11).

In some embodiments, step 109 may include depositing a conducting material (which is used to form the second conducting portion 33) over the structure shown in FIG. 11, followed by a planarization process (e.g., CMP, but is not limited thereto) to remove an excess amount of the conducting material, thereby forming the second conducting portion 33. Any suitable deposition process known in the art may be employed. The conducting material may be similar to the material of the first conducting layer 21, and thus details thereof are omitted for the sake of brevity. Other suitable materials and/or methods for forming the second conducting portion 33 are within the contemplated scope of the present disclosure. The second conducting portion 33 may serve as a via, and is known as a self-aligned via (SAV). Steps 101 to 109 as described above is a SAV process.

By completing step 109, an upper interconnect level Mₓ₊₁ is formed to include the second conducting portion 33 which is electrically connected to one of the first conducting portion 211 of the lower interconnect level Mₓ, thereby obtaining the semiconductor structure. In addition, the upper interconnect level Mₓ₊₁ (e.g., the second conducting portion 33) is spaced apart from the dielectric lower portion 271 by the etching-resistant upper portion 272.

In the case that the isolation elements includes merely the dielectric lower portion, and void formation arises in such isolation elements, the conducting material for forming the second conduction portion may also undesirably fill the void(s) of the isolation element(s). That is, the second conducting portion formed in such case extends through the upper interconnect level, and further extends into the isolation element at the lower interconnect level. In such case, the second conducting portion extending into the lower interconnect level is known as a tiger tooth. The second conducting portion, and an adjacent one of the first conducting potions become closer due to presence of the tiger tooth, which could deteriorate a time-dependent dielectric breakdown (TDDB) of the semiconductor structure (i.e., a time-dependent dielectric constant of the semiconductor structure undesirably becomes smaller). In addition, as the first and second conducting portions become closer, capacitance therebetween also undesirably becomes higher, resulting in an increased RC-delay of the semiconductor structure, thus affecting performance of the semiconductor structure.

The embodiments of the present disclosure have the following advantageous features. By determining the formula of the polymer of the etching-resistant material 26, and amount thereof, the etching-resistant material 26 is first made soluble and dispersed in the dielectric material 25 to fill the trenches 212. After the baking process, due to a relatively low surface energy, the soluble etching-resistant material 26 segregates from the dielectric material 25, so as to form the etching-resistant upper portion 272. The etching-resistant material 26 constituting the etching-resistant upper portion 272 has sufficient etching resistivity, so that the etching-resistant upper portion 272 may remain intact after the ESL breakthrough process, and thus the tiger tooth issue, as well as deterioration of TDBB, high capacitance and RC delay can be avoided, thereby improving performance of the semiconductor structure.

In accordance with some embodiments of the present disclosure, a method for manufacturing a semiconductor structure includes: forming first conducting portions that are spaced apart from each other on a base structure; forming isolation elements, each of which includes a dielectric lower portion and an etching-resistant upper portion covering the dielectric lower portion, the etching-resistant upper portion being made of an etching-resistant material different from a dielectric material of the dielectric lower portion, each of the isolation elements being isolated and exposed from two adjacent ones of the first conducting portions; sequentially forming an etch stop layer and an interlayer dielectric over the first conducting portions and the isolation elements; forming a cavity which extends through the etch stop layer and the interlayer dielectric, and which exposes one of the first conducting portions; and filling the cavity with a second conducting portion.

In accordance with some embodiments of the present disclosure, forming the isolation elements includes: forming a gap filling material layer over the first conducting portions, the gap filling material layer filling spaced-apart regions among the first conducting portions, and including the dielectric material and the etching-resistant material; performing a planarization process to remove an excess amount of the gap filling material layer, so that parts of the gap filling material layer remain and are exposed from the first conducting portions; and performing a baking process, such that in each of the parts of the gap filling material layer, the etching-resistant material segregates from the dielectric material to form the etching-resistant upper portion, and the dielectric material forms the dielectric lower portion, thereby forming the isolation elements.

In accordance with some embodiments of the present disclosure, in forming the gap filling material layer, at least one part of the etching-resistant material is soluble and dispersed in the dielectric material.

In accordance with some embodiments of the present disclosure, the etching-resistant material is a polymer having a backbone that includes a phenyl-containing repeating unit with an alkyl side chain.

In accordance with some embodiments of the present disclosure, after the baking process, the at least one part of the etching-resistant material forms as a monolayer.

In accordance with some embodiments of the present disclosure, a surface energy of the etching-resistant material is lower than a surface energy of the dielectric material.

In accordance with some embodiments of the present disclosure, the etching-resistant material is a polymer having a backbone that includes a phenyl-containing repeating unit with a fluorinated side chain.

In accordance with some embodiments of the present disclosure, the etching-resistant material is a polymer having a backbone that includes a phenyl-containing repeating unit with a silicon-containing side chain.

In accordance with some embodiments of the present disclosure, the etching-resistant upper portion includes a polymer, a repeating unit in a backbone of the polymer having at least two phenyl groups.

In accordance with some embodiments of the present disclosure, a method for manufacturing a semiconductor structure includes: forming a first conducting layer on a base structure; forming a trench in the first conducting layer, such that the first conducting layer is formed into first conducting portions spaced apart by the trench; filling the trench with a mixture including a dielectric material and an etching-resistant material which is at least partially soluble in the dielectric material and which is different from the dielectric material; performing a treatment to permit segregation of the mixture, such that the dielectric material constitutes a dielectric lower portion, and such that the etching-resistant material constitutes an etching-resistant upper portion covering the dielectric lower portion and being exposed from the first conducting portions; sequentially forming an etch stop layer and an interlayer dielectric over the first conducting portions and the etching-resistant upper portion; forming a cavity which extends through the etch stop layer and the interlayer dielectric, and which exposes one of the first conducting portions; and filling the cavity with a second conducting portion.

In accordance with some embodiments of the present disclosure, the etching-resistant material includes a polymer having the following formula (A):

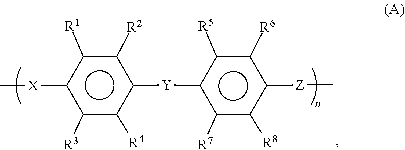

X representing

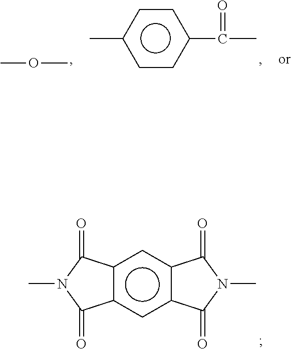

Y representing and

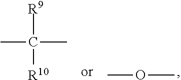

Z representing

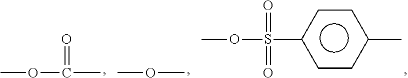

or a single bond, each of R¹, R², R³, R⁴, R⁵, R⁶, R⁷, R⁸, R⁹, R¹⁰representing one of the following formula (I), formula (II), or formula (III):

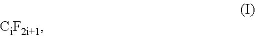

wherein i is an integer equal to or larger than 1,

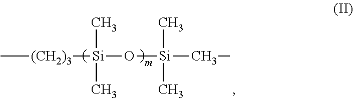

wherein m is an integer equal to or larger than 0, and
CⱼH₂ⱼ₊₁ (III),
wherein j is an integer equal to or larger than 0.

In accordance with some embodiments of the present disclosure, each of i, m and j is an integer not greater than 12.

In accordance with some embodiments of the present disclosure, X is Y

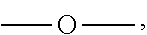

### Y

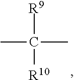

### and Z is

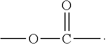

In accordance with some embodiments of the present disclosure, X is

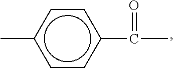

### Y is

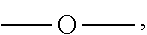

### and Z is

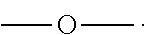

In accordance with some embodiments of the present disclosure, X is

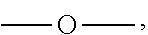

### Y is

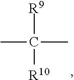

### and Z is

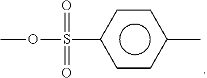

In accordance with some embodiments of the present disclosure, X is

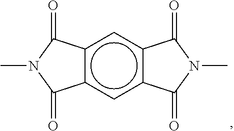

### Y is

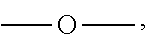

and Z is the single bond.

In accordance with some embodiments of the present disclosure, the polymer has a molecular weight ranging from 1000 to 300000.

In accordance with some embodiments of the present disclosure, the treatment is a baking process performed at a temperature of greater than 50° C.

In accordance with some embodiments of the present disclosure, a semiconductor structure includes: a base structure, a lower interconnect level formed on the base structure, and an upper interconnect level formed on the lower interconnect level opposite to the base structure. The lower interconnect level includes first conducting portions and isolation elements. Each of the isolation elements isolates two adjacent ones of the first conducting portions from each other. Each of the isolation elements includes a dielectric lower portion and an etching-resistant upper portion covering the dielectric lower portion. A surface energy of the etching-resistant upper portion being lower than a surface energy of the dielectric material. The upper interconnect level includes an etch stop layer, an interlayer dielectric and a second conducting portion. The etch stop layer and the interlayer dielectric are sequentially formed over the lower interconnect level. The second conducting portion penetrates through the etch stop layer and the interlayer dielectric, and is connected to one of the first conducting portions.

In accordance with some embodiments of the present disclosure, the upper interconnect level is spaced apart from the dielectric lower portion by the etching-resistant upper portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming first conducting portions that are spaced apart from each other on a base structure;
forming isolation elements, each of which includes a dielectric lower portion and an etching-resistant upper portion covering the dielectric lower portion, the etching-resistant upper portion being made of an etching-resistant material different from a dielectric material of the dielectric lower portion, each of the isolation elements being isolated and exposed from two adjacent ones of the first conducting portions;
sequentially forming an etch stop layer and an interlayer dielectric over the first conducting portions and the isolation elements;
forming a cavity which extends through the etch stop layer and the interlayer dielectric, and which exposes one of the first conducting portions; and
filling the cavity with a second conducting portion.

2. The method according to claim 1, wherein forming the isolation elements includes:
forming a gap filling material layer over the first conducting portions, the gap filling material layer filling spaced-apart regions among the first conducting portions, and including the dielectric material and the etching-resistant material;
performing a planarization process to remove an excess amount of the gap filling material layer, so that parts of the gap filling material layer remain and are exposed from the first conducting portions; and
performing a baking process, such that in each of the parts of the gap filling material layer, the etching-resistant material segregates from the dielectric material to form the etching-resistant upper portion, and the dielectric material forms the dielectric lower portion, thereby forming the isolation elements.

3. The method according to claim 2, wherein in forming the gap filling material layer, at least one part of the etching-resistant material is soluble and dispersed in the dielectric material.

4. The method according to claim 3, wherein the etching-resistant material is a polymer having a backbone that includes a phenyl-containing repeating unit with an alkyl side chain.

5. The method according to claim 3, wherein after the baking process, the at least one part of the etching-resistant material forms as a monolayer.

6. The method according to claim 1, wherein a surface energy of the etching-resistant material is lower than a surface energy of the dielectric material.

7. The method according to claim 6, wherein the etching-resistant material is a polymer having a backbone that includes a phenyl-containing repeating unit with a fluorinated side chain.

8. The method according to claim 6, wherein the etching-resistant material is a polymer having a backbone that includes a phenyl-containing repeating unit with a silicon-containing side chain.

9. The method according to claim 1, wherein the etching-resistant upper portion includes a polymer, a repeating unit in a backbone of the polymer having at least two phenyl groups.

10. A method for manufacturing a semiconductor structure, comprising:
forming a first conducting layer on a base structure;
forming a trench in the first conducting layer, such that the first conducting layer is formed into first conducting portions spaced apart by the trench;
filling the trench with a mixture including a dielectric material and an etching-resistant material which is at least partially soluble in the dielectric material and which is different from the dielectric material;
performing a treatment to permit segregation of the mixture, such that the dielectric material constitutes a dielectric lower portion, and such that the etching-resistant material constitutes an etching-resistant upper portion covering the dielectric lower portion and being exposed from the first conducting portions;
sequentially forming an etch stop layer and an interlayer dielectric over the first conducting portions and the etching-resistant upper portion;
forming a cavity which extends through the etch stop layer and the interlayer dielectric, and which exposes one of the first conducting portions; and
filling the cavity with a second conducting portion.

11. The method according to claim 10, wherein the etching-resistant material includes a polymer having the following formula (A): 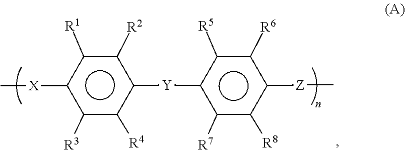
X representing 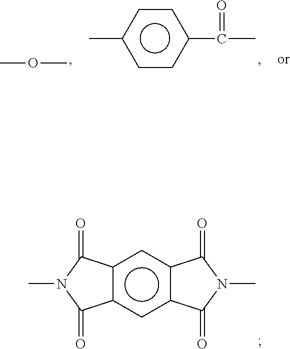
Y representing 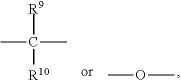
and Z representing 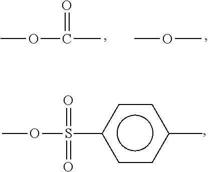
or a single bond,
each of R¹, R², R³, R⁴, R⁵, R⁶, R⁷, R⁸, R⁹, R¹⁰ representing one of the following formula (I), formula (II), or formula (III): 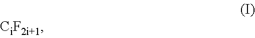
wherein i is an integer equal to or larger than 1, 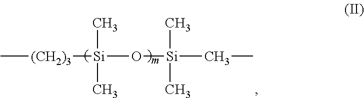
wherein m is an integer equal to or larger than 0, and
CⱼH₂ⱼ₊₁ (III),
wherein j is an integer equal to or larger than 0.

12. The method according to claim 11, wherein each of i, m and j is an integer not greater than 12.

13. The method according to claim 11, wherein X is 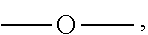
Y is 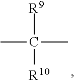
and Z is

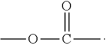

14. The method according to claim 11, wherein X is 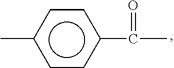
Y is 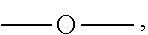
and Z is

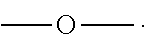

15. The method according to claim 11, wherein X is 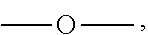
Y is 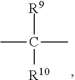
and Z is

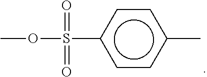

16. The method according to claim 11, wherein X is 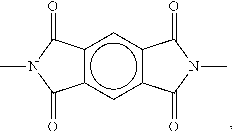
Y is 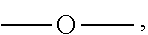
and Z is the single bond.

17. The method according to claim 10, wherein the polymer has a molecular weight ranging from 1000 to 300000.

18. The method according to claim 10, wherein the treatment is a baking process performed at a temperature of greater than 50° C.

19. A semiconductor structure, comprising:
a base structure;
a lower interconnect level formed on the base structure, and including
first conducting portions; and
isolation elements, each of the isolation elements isolating two adjacent ones of the first conducting portions from each other, each of the isolation elements including a dielectric lower portion and an etching-resistant upper portion covering the dielectric lower portion, a surface energy of the etching-resistant upper portion being lower than a surface energy of the dielectric material; and
an upper interconnect level formed on the lower interconnect level opposite to the base structure, the upper interconnect level including
an etch stop layer and an interlayer dielectric that are sequentially formed over the lower interconnect level; and
a second conducting portion that penetrates through the etch stop layer and the interlayer dielectric, and that is connected to one of the first conducting portions.

20. The semiconductor structure according to claim 1, wherein the upper interconnect level is spaced apart from the dielectric lower portion by the etching-resistant upper portion.
